(19) United States
(12) Patent Application Publication
(10) Pub. No.: US 2024/0353483 A1
(43) Pub. Date: Oct. 24, 2024

(54) METHOD AND SYSTEM FOR TESTING A CHIP

(71) Applicant: Lenovo (Singapore) Pte, Ltd., Singapore (SG)

(72) Inventors: Xueyong Yang, Kanagawa (JP); Satoshi Yamazaki, Kanagawa (JP)

(73) Assignee: Lenovo (Singapore) Pte, Ltd., Singapore (SG)

(21) Appl. No.: 18/304,617

(22) Filed: Apr. 21, 2023

(51) Int. Cl. G01R 31/28; G01R 1/04

(52) U.S. Cl. CPC G01R 31/2889; G01R 1/0416

(57) ABSTRACT

A method and a system for testing various types of chips includes: registering, by a tester connected to a chip, a model pattern of signals; receiving, by the tester via no more than a single cable, an output signal generated by the chip based on a test signal generated by the tester or by an image sensor connected to the chip; comparing, by the tester, a pattern in the output signal with the model pattern of signals; and displaying, by a display, a test result based on a comparison of the pattern in the output signal with the model pattern of signals.

### TECHNICAL FIELD

The present invention relates to chip testing, and more particularly to a method and a system for testing computer chips compatible with mobile industry processor interface (MIPI) specifications.

### BACKGROUND

Computer chips are the driving force for the development of high-performance digital gadgets. For example, specialized chips such as digital signal processors (DSPs) are integrated into imaging modules not only to run oscilloscopes, printers, and mobile phones, but also laptops and desktop computers. As another example, computer vision (CV) chips are used for video conferences on a computer screen by transmitting a user's real-time facial expression.

Chips are not immune from production errors. Even a minor technical imperfection in a chip can adversely affect the device performance. Thus, screening chips before assembly into final products is desirable to ensure the quality and performance of the products. This includes testing the performance of the device based on the MIPI standard, which is a standardized processor interface for connecting cameras and displays of mobile devices. However, when different chips are installed into different mobile devices such as smartphones, tablets, or laptops, the screening process may require an individualized MIPI tester consisting of a specific set of components. Making and using such specialized MIPI testers for every mobile device could be both impractical and uneconomical.

In a camera subsystem design for a laptop with a clamshell form factor, either standard MIPI or USB interface specification has its own imperfection to implement. Higher image quality by raw data using MIPI interface without compression is desired by users rather than USB interface. However, it introduces several side band control signals to be routed together which increase the limitation on modern laptop's mechanical design to consider how to route all signals together through a narrowly structured hinge with a limited diameter of hinge hole. Hence, aggregating all side band signals via a USB interface, and keep transferring image raw data via MIPI interface is considered.

### SUMMARY

In general, one or more embodiments of the invention relate to a method of testing a chip compatible with MIPI interfaces and cables. The method comprises: registering, by a tester connected to a subsystem with a chip, a model pattern of signals; receiving, by the tester via no more than a single cable, an output signal generated by the chip based on a test signal; comparing, by the tester, a pattern in the output signal with the model pattern of signals; and displaying, by a display, a test result based on a comparison of the pattern in the output signal with the model pattern of signals.

In general, one or more embodiments of the invention relate to a system for testing a chip compatible with MIPI interfaces and cables. The system comprises: a tester connected to a subsystem with a chip; and a display connected to the tester, wherein the tester: registers a model pattern of signals; receives, via no more than a single cable, an output signal generated by the chip based on a test signal generated by the tester or an image sensor connected to the chip; compares a pattern in the output signal with the model pattern of signals; and causes the display to display a test result based on a comparison of the pattern in the output signal with the model pattern of signals.

Other aspects of the invention will be apparent from the following description and the appended claims.

### BRIEF DESCRIPTION OF DRAWINGS

FIGS. 1A and 1B show a schematic perspective view and a schematic side view, respectively, of a device with a chip whose function can be tested according to one or more embodiments.

FIG. 2 is an overview of a system for testing a chip, including a tester, according to one or more embodiments.

FIG. 3 shows a screen of a tester's display according to one or more embodiments.

FIG. 4 shows a functional block diagram of a system for testing a CV chip according to one or more embodiments.

FIG. 5 shows a functional block diagram of a tester according to one or more embodiments.

FIGS. 6A and 6B show functional block diagrams of the system for testing a CV chip according to one or more embodiments.

FIG. 7 shows a schematic view of an implementation example of the system for testing a CV chip according to one or more embodiments.

FIG. 8 shows a schematic diagram of an implementation example of signal aggregation in the system.

FIG. 9 shows a flowchart of a method for testing a chip according to one or more embodiments.

### DETAILED DESCRIPTION

Specific embodiments of the invention will now be described in detail with reference to the accompanying figures. Like elements in the various figures are denoted by like reference numerals for consistency.

In the following detailed description of embodiments of the invention, numerous specific details are set forth taking a CV chip as an example of a chip in some instances in order to provide a more thorough understanding of the invention. However, it will be apparent to one of ordinary skill in the art that the invention may be practiced in any chip compliant with MIPI standard, without these specific details. In other instances, well-known features have not been described in detail to avoid unnecessarily complicating the description.

In general, one or more embodiments provide a method and a system for testing a chip compatible with MIPI interfaces/cables which allows for efficient detection of faulty chips without regard to the specific type of chip. This is achieved, for example, by registering a model pattern of signals and comparing (for example, identifying similarities between) a pattern in an output signal of a chip with the model pattern of signals expected to be transmitted from the chip and by utilizing a test chip, a copy of the chip, for registration of the normal pattern of signals. This achieves improved interoperability with different types of chips and efficiency of testing the tests.

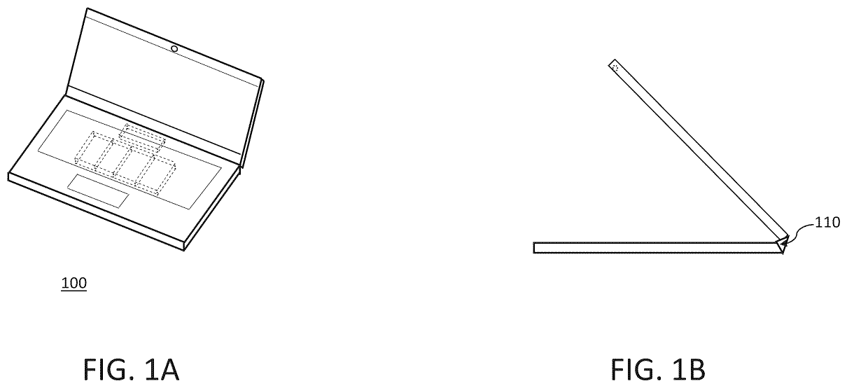

FIGS. 1A and 1B show schematic views of a computer device 100. Although the device 100 is shown as a laptop or notebook computer for purposes of illustration, for purposes of the invention the device 100 is not limited to any specific type or product. For example, the device 100 may also be a desktop computer, smart phone, personal digital assistant, tablet computer, etc.

The device 100 may include a chip (not shown). For reasons discussed above, the chip may require testing prior to installation.

The device 100 may further include a hinge 110. In some embodiments, a connection between a component in the upper chassis of the device 100 and a component in the lower chassis of the device 100 runs through the hinge 110.

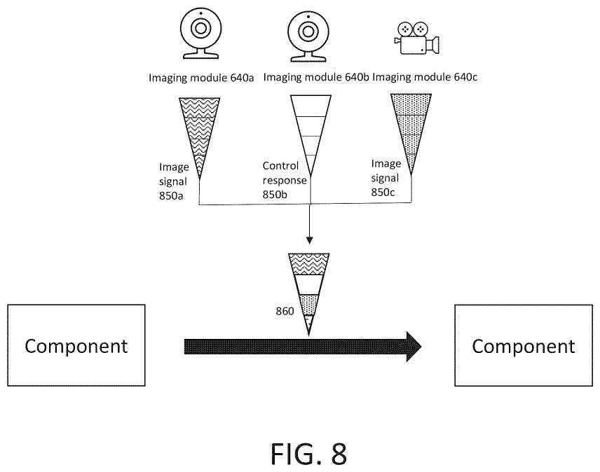

In accordance with one or more embodiments, the connection may be established by as many as twenty five wirings, including a MIPI cable. For reasons discussed above, the reduction of the amount of wirings is eagerly sought for to enhance the functionality of the device 100 without sacrificing the reliability of the connection. The reduction of the amount of wiring is achieved by the method discussed later (shown in FIG. 8).

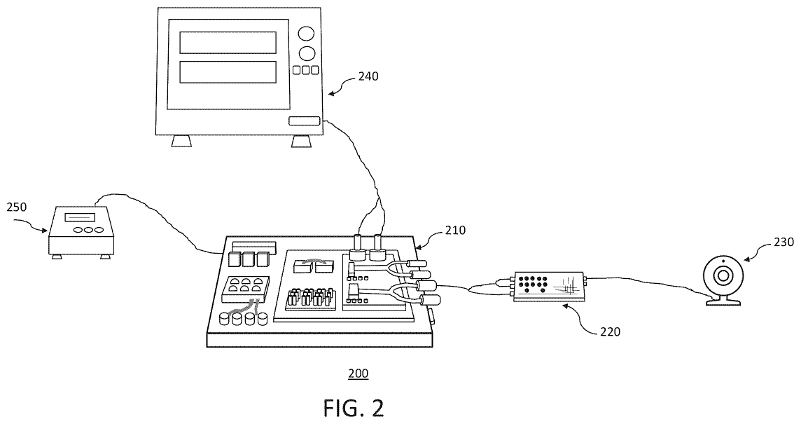

FIG. 2 illustrates an example of a system 200 for testing the CV chip according to one or more embodiments.

In some embodiments, the system 200 may utilize live image data to test the CV chips 220. In such embodiments, as shown in FIG. 2, the system 200 includes a tester 210, the subsystem with the CV chip 220 (under test), an image sensor 230, a display 240, and a power supply 250 with an on/off switch. The subsystem with the CV chip 220 may consist of a processor, a module, a sub board (sub-card), a system on chip (SOC), an information processing electronic circuitry, or a field programmable gate array (FPGA). For each type of the subsystems with the CV chip 220, a test may be performed as shown in FIG. 2.

In one or more embodiments, the system 200 initiates a test on the CV chip 220 when the power supply 250 is turned on by an operator. The tester 210 directs an image capture by the image sensor 230.

For example, as implemented in FIG. 2, the tester 210 transmits an instruction for test initiation to the image sensor 230, indirectly via the CV chip 220. If the CV chip 220 correctly relays the instruction, the image sensor 230 will capture an image or generate a specific image pattern as requested. On the other hand, if the image sensor 230 does not capture an image after the power supply 250 is turned on, the tester 210 detects the CV chip's 220 failure to convey the instruction to the image sensor 230.

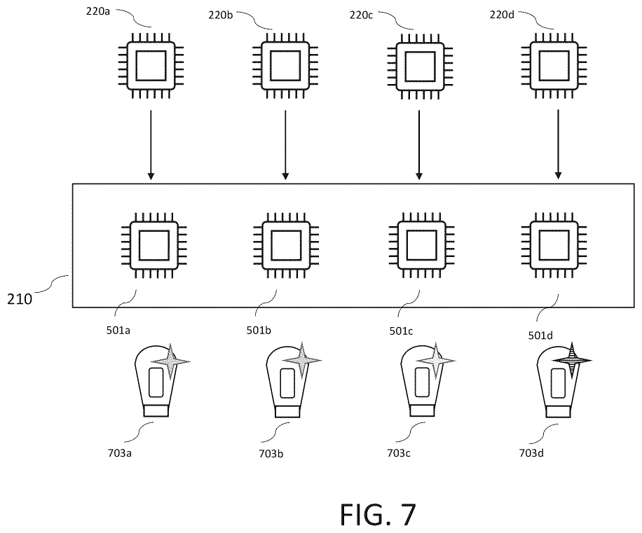

Although there is only one image sensor 230 connected to the CV chip 220 in the exemplary system 200, the invention is not limited to image data from a single sensor, as will be explained with regards to FIG. 7. The CV chip 220 is connected to the image sensor 230 such that image data (e.g., data of a photograph) can be transmitted from the image sensor 230 to the CV chip 220.

Still at FIG. 2, when the image sensor 230 captures an image of an object, image data is generated by the image sensor 230 and transmitted to the tester 210. In some implementations, the CV chip 220 processes the image data and transmits an output signal to the tester 210 via a general-purpose cable. In other implementations, the CV chip 220 transmits an output signal to the tester 210 without processing the image data.

Following the transmission of the output signal by the CV chip 220, the tester 210 receives the output signal and compares a pattern in the output signal with a model pattern of signals. If there is enough similarity between the model pattern of signals and the pattern in the output signal, considering the average level of noise in signal transmissions, the tester 210 determines that the CV chip 220 passed the test. If not, the tester 210 concludes that the CV chip 220 failed the test.

The test result thus obtained is conveyed from the tester 210 to the display 240. The display 240 may be a screen of a computer device, as shown in FIG. 2. For purposes of the invention, the display 240 is not limited to a screen of a computer, and a person with ordinary skill in the art may adopt other modalities as the display 240, including a mobile device and a wearable device. In those circumstances, the display 240 may be wirelessly connected to the tester 210.

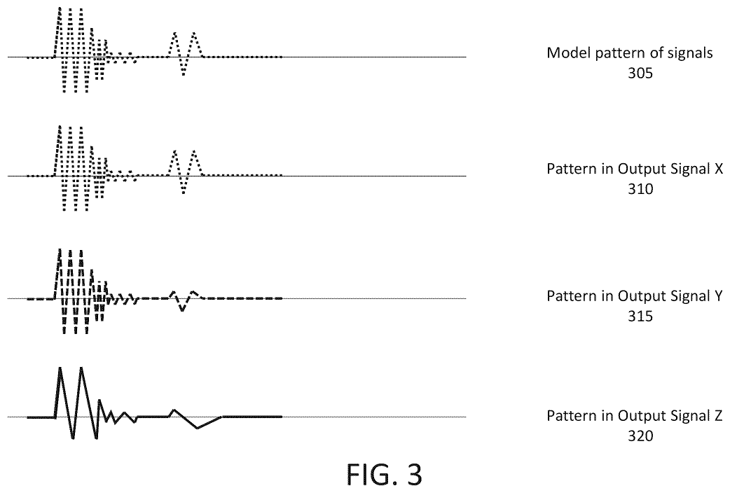

Moving on to FIG. 3, showing an implementation example of a screen of the tester's display 240. In this example, the tester 210 performs a test simultaneously on three CV chips 220. As can be seen, the screen shows a test result based on the comparison of a model pattern of signals 305 with a pattern in Output Signal X 310, a pattern in Output Signal Y 315, and a pattern in Output Signal Z 320. As a result, any difference among the patterns can be easily identified. In the example shown, the pattern in Output Signal X 310 and the pattern in Output Signal Y 315 are equivalent to the model pattern of signals 305, and the pattern in Output Signal Z 320 is different from the model pattern of signals 305.

In one or more embodiments, instead of the figurative illustration of observed patterns (e.g., wave pattern) as depicted in FIG. 3, the test result may be verbally shown (e.g., letter “P” for passing).

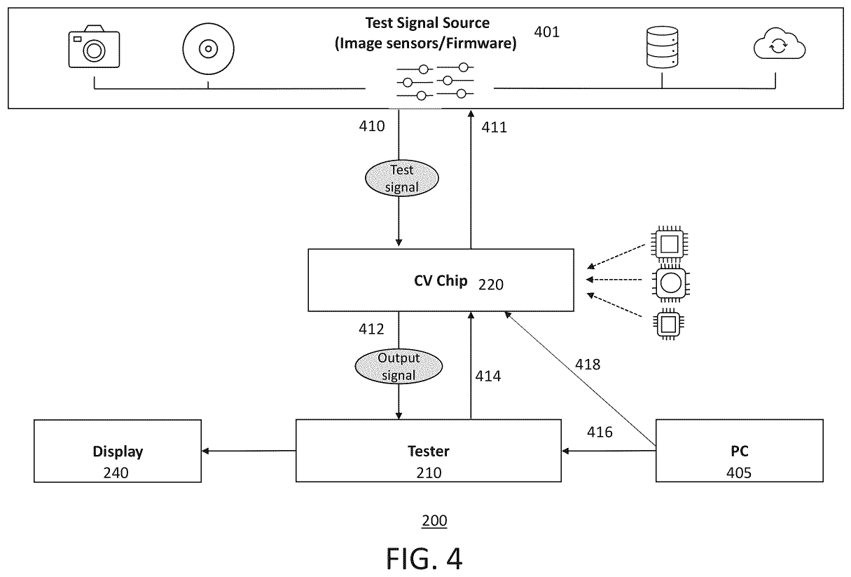

Next, FIG. 4 shows a functional block diagram of another example of the system 200 discussed with reference to FIG. 2. Instead of the power supply 250 shown in FIG. 2, the system 200 includes a personal computer (PC) 405. Further, the system 200 includes a test signal source 401 as a source of data input, and the tester 210 may receive a test signal from a wide range of signal sources (including image data stored in the tester 210). Also included in the system 200 are the tester 210, the CV chip 220, the display 240, and cables 410, 411, 412.

The CV chip 220 that is tested may be at a wafer designing stage, a module development phase, a device installation stage, or a manufactured stage.

As explained above, the system 200 tests the CV chip 220 using a test signal produced by various types of sources. In the embodiments in which the test signal source 401 is the image sensor 230, the CV chip 220 may be connected to other components in an imaging module 640. For example, the CV chip 220 receives image data from the image sensor 230 when the image sensor 230 acquires an image. In another embodiment, a computer program stored in a server or in the tester 210 provides standard data to the CV chip 220 as a test signal. While the former embodiments can test the CV chip 220 more comprehensively, inclusive of the connections between the CV chip 220 and other components, the latter embodiment examines only the CV chip 220 in a more efficient manner.

Referring back to FIG. 4, the system 200 initiates a test once the PC 405 receives an input to initiate a test. In some embodiments, the initiation instruction is then conveyed to the tester 210, to the CV chip 220, and to the test signal source 401, through connections 416, such as Universal Serial Bus (USB). If the input is properly processed by the CV chip 220 and both the connection between the CV chip 220 and the tester 210 and the connection between the CV chip 220 and the test signal source 401 remain intact, an image is acquired by the test signal source 401.

In such implementations, the test signal source 401 generates and transmits a test signal (image data) to the CV chip 220. For this implementation, the connection between the CV chip 220 and the image signal source 401 may be provided with a cable which consists of high-speed differential signals follow MIPI specification (410), and all necessary side band control signals (411). An output signal is generated based on the received test signal.

Once the output signal is received from the CV chip 220 through the cable 412, the tester 210 performs a test on the output signal.

In one example, the processor of the tester 210, after performing a test, may return a test result to the display 240 indicating a failure of the CV chip 220 if there is a pattern abnormality. The display 240 may be connected to the tester 210 via any suitable cable. Additionally, for purposes of the invention, the display 240 may be wirelessly connected to the tester 210.

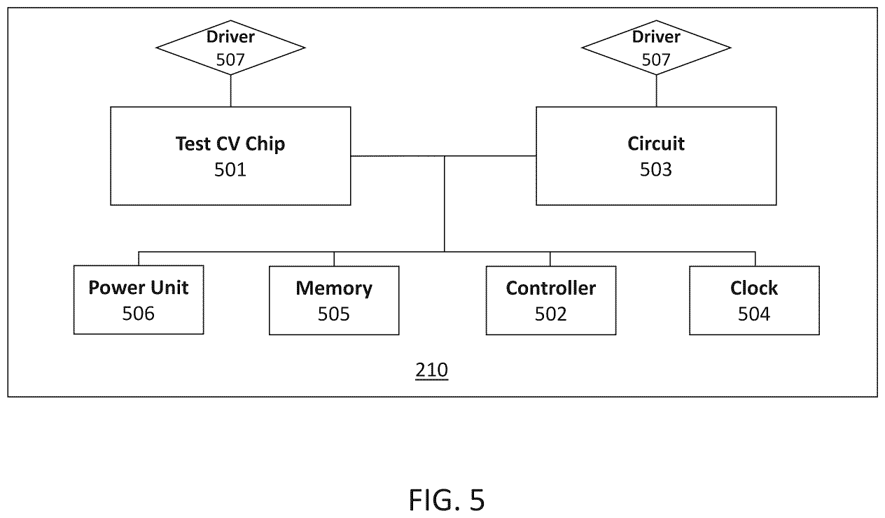

Moving on, FIG. 5 shows a functional block diagram of the tester 210 according to one or more embodiments. In this example, the tester 210 includes a circuit 503, a test CV chip (“test CV chip” includes a companion CV chip of the CV chip 220 being tested) 501, a power unit 506, a memory 505, a controller 502, a clock 504, and a driver 507.

The test CV chip 501 may register the model pattern of signals which serves as a reference in a test. Because the test CV chip 501 has the same circuitry with the CV chip 220, the model pattern of signals may be generated by the test CV chip 501 with an input of a test signal. The use of the test CV chip 501 this way saves the trouble of programming a complex software that comprehensively tests a large pool of logic potentially executable in programmable CV chips 220.

In relation to various functions carried out by the tester 210 in a test of a CV chip 220, the controller 502 coordinates processes being performed at different modules. For example, to detect a defective circuitry in the CV chip 220, the controller 502 refers to the model pattern of signals registered at the test CV chip 501. First, because the test CV chip 501 is expected to return an output signal identical or equivalent to an output signal from the CV chip 220, any noticeable difference between the pattern in the output signal and the model pattern of signals raises the possibility of abnormality. Thus, the detection of an abnormal output signal becomes a quicker and simpler process. Second, because the model pattern of signals does not require more than the test signal to be received by the test CV chip 501, there is no need for the tester 210 to produce a different testing protocol to reflect a renewed or added logic for the CV chip 220, even when the CV chip 220 is programmable.

As such, the method of testing the CV chip 220 is executable in an expedited manner, in accordance with one or more embodiments. In some embodiments, once the tester 210 is connected to the CV chip 220 and the test CV chip 501, the tester 210 enters a standby state in which the tester 210 may receive an initiation instruction from the PC 405. The instruction to start a test may be communicated to the power unit 506 and the clock 504.

Subsequent to the receipt of the instruction from the PC 405, in some cases, the controller 502 sends an instruction to the test CV chip 501, requesting registration of the model pattern of signals. In other embodiments, the instruction to start a test may be communicated directly to the test CV chip 501. The test CV chip 501 may generate the model pattern of signals for instance, by producing its own output signal after receiving the test signal. In this implementation, the test signal is first transmitted to the CV chip 220 and is relayed to the test CV chip 501 together with the CV chip's 220 output signal. Alternatively, the controller 502 retrieves the model pattern of signals from the memory 505 so that a pattern in the output signal can be compared with the retrieved model pattern of signals at the test CV chip 501.

Still at FIG. 5, after the model pattern of signals is generated, for example at the test CV chip 501, the system 200 proceeds to analyze a pattern in the output signal of the CV chip 220. Since the test CV chip 501 is made identical to the CV chip 220, the test CV chip 501 may determine whether a pattern in the output signal is identical or equivalent to the model pattern of signals after registering the model pattern of signals.

FIG. 7 shows a schematic view of an implementation example of the system 200 according to one or more embodiments. In the system 200 for testing multiple CV chips 220, the tester 210 may accommodate a group of CV chips (220a, 220b, 220c, 220d) to perform tests simultaneously. The tester 210 receives the same number of test CV chips (501a, 501b, 501c, 501d) to perform tests on the four CV chips (220a, 220b, 220c, 220d) in some implementations. Alternatively, the tester 210 may have only one test CV chip for testing multiple CV chips (220a, 220b, 220c, 220d) as long as the multiple CV chips (220a, 220b, 220c, 220d) have the identical design with each other.

In implementations like the one in FIG. 7, lighting devices (703a, 703b, 703c, 703d) function as the display 240. In such implementations, the tester 210 may return test results of the tests on the CV chips (220a, 220b, 220c, 220d) by transmitting a command to the lighting devices (703a, 703b, 703c, 703d) to emit light. The color of light indicates the test result. For example, green light signals a pass and red light signals a failure. The lighting device 703 may be comprised of a board and an LED light.

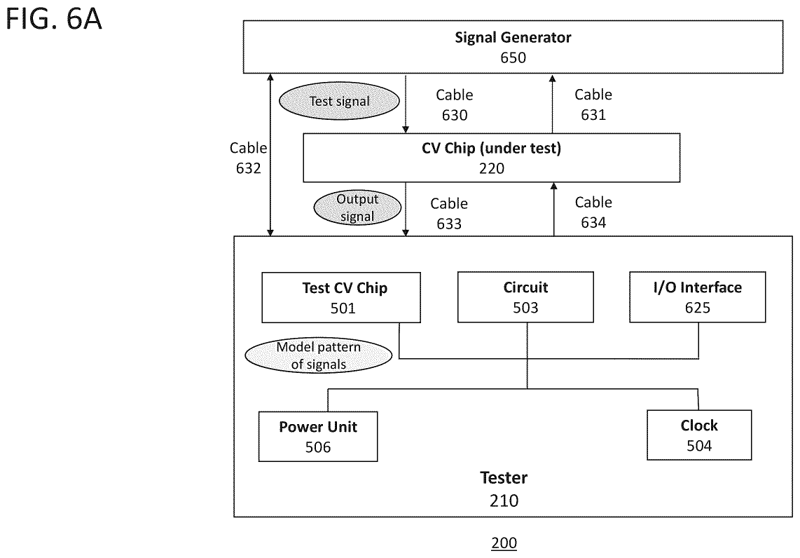

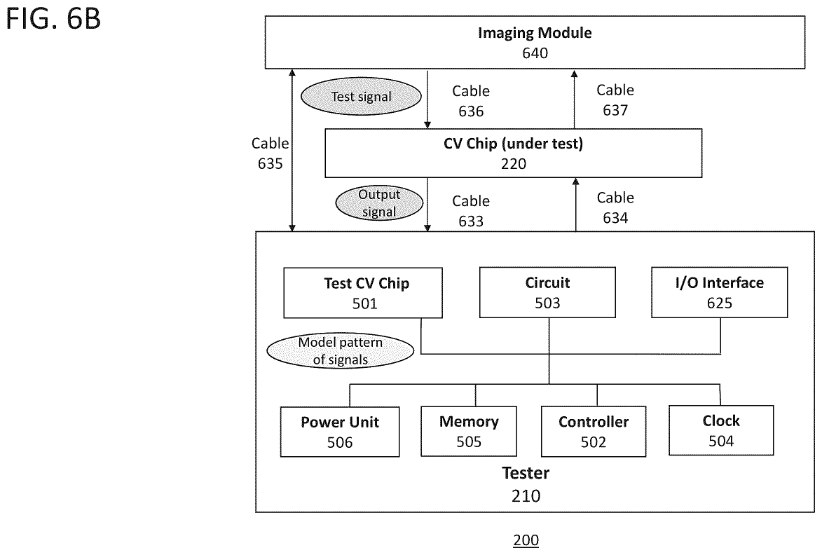

FIGS. 6A and 6B show functional block diagrams of the system 200 for testing the CV chip 220, in accordance with one or more embodiments. FIGS. 6A and 6B illustrate how a test signal is obtained and used for testing the CV chip 220. For example, the system 200 may utilize an artificially created test signal from the test signal source 401 (e.g., an output from a signal generator 650), in place of a live test signal that the image sensor 230 transmits to the CV chip 220 after acquiring an image.

FIG. 6A shows the system 200 in which a test signal is provided from the signal generator 650. The signal generator 650 may include a memory, a controller, and an I/O interface. The signal generator 650 may be connected to the tester 210 via cables (630, 631, 632, 633, 634), and to the CV chip 220 via cables (630, 631). The signal generator 650 may receive an instruction to start a test from the tester 210 via cables (631, 634).

As shown in FIG. 6A, the signal generator 650 may provide a test signal to both the CV chip 220 via a cable 630 and the test CV chip 501 via a cable 632. For example, the CV chip 220 may process the test signal and produce an output signal. Then, the output signal of the CV chip 220 may be transmitted to the test CV chip 501 to be compared with the model pattern of signals. In one or more implementations, the test CV chip 501 receives and processes the test signal to produce the model pattern of signals.

The tester 210 instructs the test CV chip 501 to compare the pattern in the output signal with the model pattern of signals and determine whether the CV chip 220 has a defective circuitry. The controller 502 may use any suitable known method for detecting an abnormal pattern, a disparity from the model pattern of signals, in the output signal.

FIG. 6B shows another example of the system 200 in which the test signal is provided from the imaging module 640. In the system 200 depicted in FIG. 6B, the test signal (image data) is generated at the imaging module 640 which may include the image sensor 230 as a component. For example, the imaging module 640 may be connected to the CV chip 220 via cables (636, 637), and may receive an instruction to start an image acquisition from the CV chip 220 via a cable (637). Optionally, the instruction may be transmitted from the tester 210 to the image sensor 230 via a cable (635).

As shown in FIG. 6B, the imaging module 640 may provide the test signal to the CV chip 220 via a cable 636 and to the test CV chip 501 via a cable 635. The CV chip 220 may process the test signal and produce an output signal. The output signal of the CV chip 220 may be transmitted to the tester 210 to be compared with the model pattern of signals in one implementation of the system. As for the model pattern of signals, the test CV chip 501 may process the test signal and produce the model pattern of signals. The model pattern of signals may be retrieved from the memory 505.

The tester 210 may instruct the test CV chip 501 to compare a pattern in the output signal with the model pattern of signals and determine whether the CV chip 220 has a defective circuitry. The tester 210 may use any suitable known method for detecting an abnormal pattern in the output signal.

FIG. 8 shows a schematic diagram of an implementation example of signal aggregation in the system 200, in accordance with one or more embodiments.

In some examples in which the signal aggregation involves the tester 210 of the CV chip 220, the image sensors 230 in the imaging modules (640a, 640b, 640c) provide test signals along with other signals related to feedbacks to command signals to the CV chip 220.

In some embodiments, the test signals and other signals from the imaging modules (640a, 640b, 640c) are combined for transmission to the tester 210. Optionally, only the test signals are aggregated and the other signals 850b are not combined with the test signals 850a, 850c before transmission. By allowing a single cable transmission, the system 200 may reduce the number of wires required for the signal transmission to the tester 210 by 40% or more, in accordance with one or more embodiments.

In yet other embodiments, signals transmitted between components located in the upper chassis of the device 100 and the lower chassis of the device 100 by multiple wirings may be aggregated in a similar manner. The aggregation of signals will reduce the space needed for wirings in the hinge 110 and promote the device design.

In general, the implementation of the system 200 described above and in FIG. 6A and FIG. 6B works as follows.

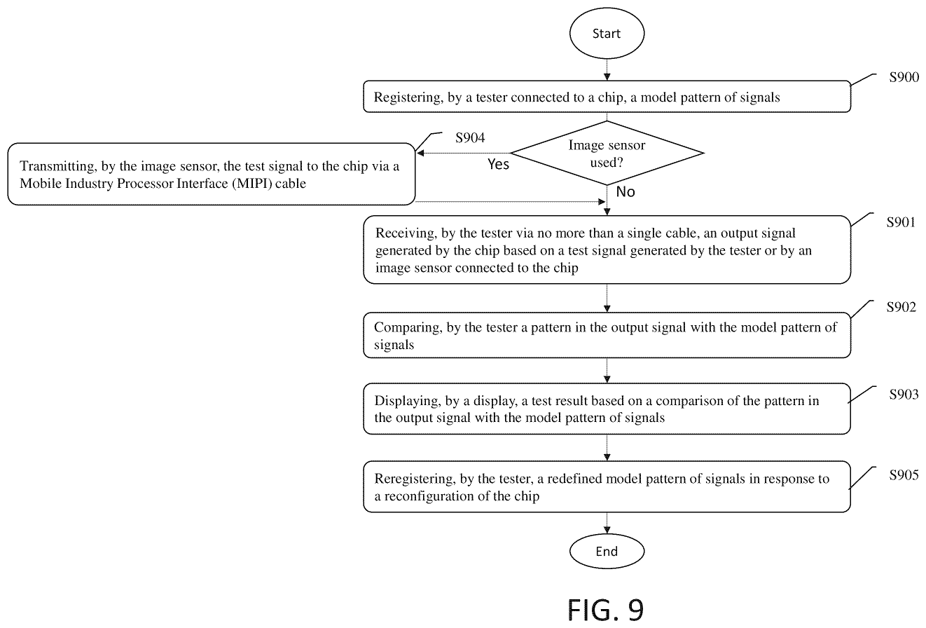

FIG. 9 is a flowchart of methods for testing a CV chip, according to one or more embodiments. One or more individual processes shown in FIG. 9 may be omitted, repeated, and/or performed in a different order than the order shown. Accordingly, the scope of the invention should not be limited by the specific arrangement as depicted in FIG. 9.

At S900 of FIG. 9, a model pattern of signals is registered by a tester 210 connected to a CV chip 220. In one embodiment, a test CV chip 501 processes a test signal received directly from the CV chip 220 and produces the model pattern of signals. In another embodiment, a controller 502 of the tester 210 retrieves the model pattern of signals from a memory 505 and registers the model pattern of signals at the test CV chip 501.

If an image sensor 230 is used, the step proceeds to S904. If no image sensor 230 is used, the step proceeds to S901.

At S904, the image sensor 230 of the imaging module 640 acquires an image in accordance with an instruction from the CV chip 220 and transmits a test signal (image data) to the CV chip 220 via a connection, such as MIPI cable 636. The test signal may also be transmitted to the test CV chip 501 for generation of the model pattern of signals.

At S901, the tester 210 receives the output signal of the CV chip 220 that is generated based on the test signal produced by the tester 210, the signal generator 650, or by the image sensor 230 connected to the CV chip 220. The output signal is transmitted from the CV chip 220 to the tester 210 via a single cable.

At S902, the tester 210 compares a pattern in the output signal from the CV chip 220 with the model pattern of signals. In some embodiments, per a command from the controller 502, the test CV chip 501 may detect a different pattern in the compared patterns because the output signal of the CV chip 220 should have an identical pattern to the model pattern of signals. The test CV chip 501 may augment the difference in the compared patterns by any method, such as the support vector clustering.

At S903, the display 240 displays a test result based on a comparison of the pattern in the output signal with the model pattern of signals. The tester 210, after obtaining a test result on the CV chip 220, transmits a command to the display 240 to indicate the test result. The test result may be specified by light emission of different colors.

At S905, the tester 210 registers a redefined model pattern of signals in response to a reconfiguration of the CV chip 220. When there has been any change to the design, such as the pool of logic, of the CV chip 220, the model pattern of signals may be redefined by generating the redefined model pattern of the signals at the test CV chip 501 after transmitting a test signal to the test CV chip 501 and obtaining an output from the test CV chip 501, or by creating a revised test code reflecting the changes in the CV chip 220.

One or more of the embodiments of the invention may offer a universal system and a method of testing a chip through the comparison of a model pattern of signals with a pattern in an output signal, which is transmitted from the chip to the tester via no more than a single cable.

Although the invention has been described with respect to a limited number of embodiments, those skilled in the art, having benefit of this disclosure, will appreciate that various other embodiments may be devised without departing from the scope of the present invention. Accordingly, the scope of the invention should be limited only by the attached claims.

What is claimed is:

1. A testing method for a chip, comprising:
registering, by a tester connected to the chip, a model pattern of signals;
receiving, by the tester via no more than a single cable, an output signal generated by the chip based on a test signal generated by the tester or by an image sensor connected to the chip;
comparing, by the tester, a pattern in the output signal with the model pattern of signals; and
displaying, by a display, a test result based on a comparison of the pattern in the output signal with the model pattern of signals.

2. The testing method of claim 1, wherein the comparing of the pattern in the output signal with the model pattern of signals is performed by a test chip on the tester.

3. The testing method of claim 1, wherein the output signal is aggregated with other signals including a command response of the image sensor, and the output signal aggregated with the other signals is received via the signal cable.

4. The testing method of claim 1, wherein the single cable is a Universal Serial Bus (USB) cable.

5. The testing method of claim 1, wherein the model pattern of signals is an artificial pattern of signals.

6. The testing method of claim 3, further comprising:
registering, by the tester, a redefined model pattern of signals in response to a reconfiguration of the chip.

7. The testing method of claim 1, further comprising:
transmitting, by the image sensor, the test signal to the chip via a Mobile Industry Processor Interface (MIPI) cable.

8. A system for testing a chip, comprising:
a tester connected to the chip; and
a display connected to the tester,
wherein the tester:
registers a model pattern of signals;
receives, via no more than a single cable, an output signal generated by the chip based on a test signal generated by the tester or an image sensor connected to the chip;
compares a pattern in the output signal with the model pattern of signals; and
causes the display to display a test result based on a comparison of the pattern in the output signal with the model pattern of signals.

9. The system according to claim 8, wherein the tester comprises a test chip that compares the pattern in the output signal with the model pattern of signals.

10. The system according to claim 8, wherein the output signal is aggregated with other signals including a command response of the image sensor, and the output signal aggregated with the other signals is received via the signal cable.

11. The system according to claim 8, wherein the single cable is a Universal Serial Bus (USB) cable.

12. The system according to claim 8, wherein the model pattern of signals is an artificial pattern of signals.

13. The system according to claim 10, wherein the tester further registers a redefined model pattern of signals in response to a reconfiguration of the chip.

14. The system according to claim 8, wherein the image sensor transmits the test signal via a Mobile Industry Processor Interface (MIPI) cable.
